(19) United States
(12) Patent Application Publication
(10) Pub. No.: US 2026/0348002 A1
(43) Pub. Date: Nov. 5, 2026

(54) FILM-FORMING METHOD AND FILM-FORMING APPARATUS

(71) Applicant: Tokyo Electron Limited, Tokyo (JP)

(72) Inventors: Daichi ITO, Yamanashi (JP); Jun OGAWA, Yamanashi (JP)

(21) Appl. No.: 19/650,599

(22) Filed: Apr. 17, 2026

(30) Foreign Application Priority Data
May 1, 2025 (JP) 2025-076240

(51) Int. Cl. C23C 16/04; C23C 16/34; C23C 16/36; C23C 16/52; C23C 16/56

(52) U.S. Cl. CPC C23C 16/045; C23C 16/345; C23C 16/36; C23C 16/52; C23C 16/56

(57) ABSTRACT

A film-forming method includes forming a protective film on a surface of a recess formed in a substrate and on a surface surrounding the recess, forming a first nitride film on the protective film, exposing a part of the protective film from the first nitride film while the first nitride film that is formed on a bottom surface of the recess remains, by supplying an etching gas to the substrate, and forming a second nitride film on the protective film and the first nitride film after the exposing of the part of the protective film. The protective film has a higher etching resistance to the etching gas than the first nitride film.

### CROSS-REFERENCE TO RELATED APPLICATIONS

This application claims priority to Japanese Patent Application No. 2025-076240, filed May 1, 2025, the entire content of which is incorporated herein by reference.

### BACKGROUND

### 1. Technical Field

The present disclosure relates to a film-forming method and a film-forming apparatus.

### 2. Description of Related Art

Japanese Unexamined Patent Application Publication No. 2022-113991 (hereinafter "Patent Document 1") discloses a technique for depositing a silicon film on recess surfaces by repeating film formation and etching.

### SUMMARY

A film-forming method according to one aspect of the present disclosure includes forming a protective film on a surface of a recess formed in a substrate and on a surface surrounding the recess, forming a first nitride film on the protective film, exposing a part of the protective film from the first nitride film while the first nitride film that is formed on a bottom surface of the recess remains, by supplying an etching gas to the substrate, and forming a second nitride film on the protective film and the first nitride film after the exposing of the part of the protective film. The protective film has a higher etching resistance to the etching gas than the first nitride film.

### BRIEF DESCRIPTION OF THE DRAWINGS

FIG. 1 is a vertical cross-sectional view illustrating a film-forming apparatus according to an embodiment;

FIG. 2 is a horizontal cross-sectional view illustrating the film-forming apparatus according to the embodiment;

FIG. 3 is a flowchart illustrating a film-forming method according to an embodiment;

FIG. 4 is a cross-sectional view (1) illustrating the film-forming method according to the embodiment;

FIG. 5 is a cross-sectional view (2) illustrating the film-forming method according to the embodiment;

FIG. 6 is a cross-sectional view (3) illustrating the film-forming method according to the embodiment;

FIG. 7 is a cross-sectional view (4) illustrating the film-forming method according to the embodiment;

FIG. 8 is a cross-sectional view (5) illustrating the film-forming method according to the embodiment;

FIG. 9 is a diagram illustrating an etching amount of a SiN film and an etching amount of a SiCN film; and

FIG. 10 is of schematic diagrams of examples of cross-sectional images.

### DETAILED DESCRIPTION

The present disclosure provides a technique for reducing etching damage to recess surfaces.

Non-limiting exemplary embodiments of the present disclosure will be described below with reference to the accompanying drawings. In all of the accompanying drawings, the same or corresponding members or components are denoted by the same or corresponding reference numerals, and redundant descriptions will be omitted.

### Film-Forming Apparatus

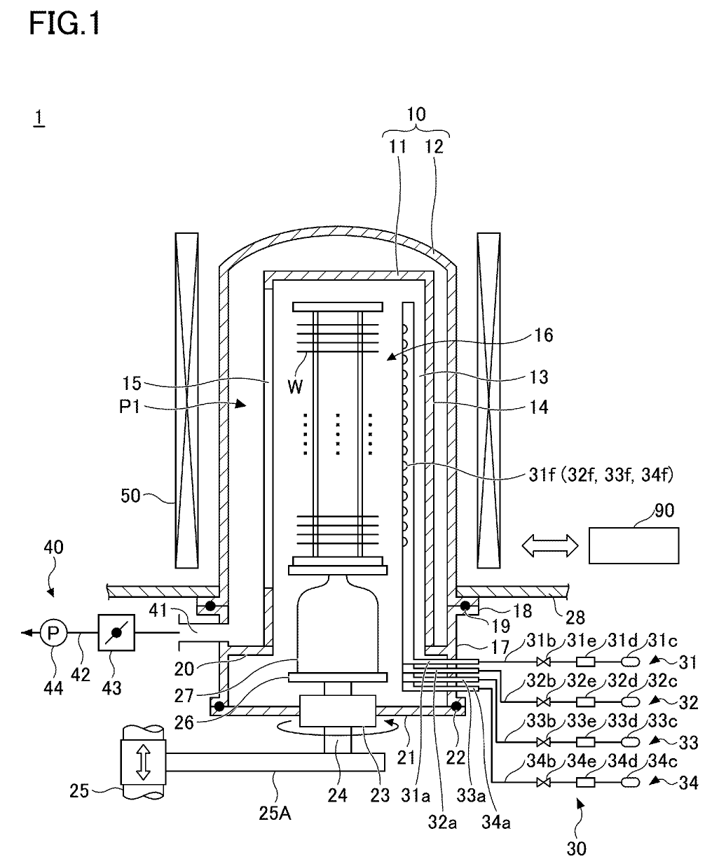

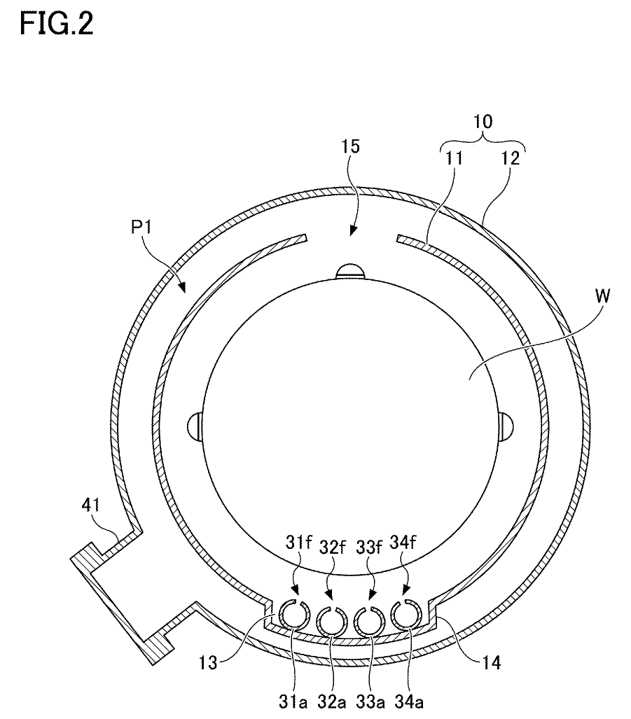

FIG. 1 is a vertical cross-sectional view illustrating a film-forming apparatus 1 according to an embodiment. FIG. 2 is a horizontal cross-sectional view illustrating the film-forming apparatus 1 according to the embodiment.

The film-forming apparatus 1 is a batch-type apparatus which processes a plurality of substrates W, for example, 50 to 150 substrates W in a batch. The substrate W is, for example, a semiconductor wafer. The film-forming apparatus 1 includes a processing chamber 10, a gas supply 30, an exhaust assembly 40, a heater 50, and a controller 90.

The processing chamber 10 can be depressurized internally. The processing chamber 10 accommodates a substrate W. The processing chamber 10 includes an inner cylinder 11 and an outer cylinder 12. The inner cylinder 11 has a cylindrical shape with a ceiling and an open bottom. The outer cylinder 12 also has a cylindrical shape with a ceiling and an open bottom and is configured to enclose the inner cylinder 11. The inner cylinder 11 and the outer cylinder 12 are formed of a heat-resistant material such as quartz. The inner cylinder 11 and the outer cylinder 12 have a double-cylinder structure coaxially arranged.

A housing part 13 for accommodating gas supply pipes is formed in the side wall of the inner cylinder 11 along a vertical direction. For example, a portion of the side wall of the inner cylinder 11 is formed to protrude outward, thereby forming an expanded portion 14, and the interior of the expanded portion 14 serves as the housing part 13.

A rectangular opening 15 is formed in the side wall of the inner cylinder 11 along the vertical direction. The opening 15 faces the housing part 13.

The opening 15 is a gas exhaust port formed to exhaust gas in the inner cylinder 11. The length of the opening 15 is the same as the length of a boat 16 or longer than the length of the boat 16.

The lower end of the processing chamber 10 is supported by a manifold 17 having a cylindrical shape. The manifold 17 is formed of, for example, stainless steel. A flange 18 is formed at the upper end of the manifold 17. The flange 18 supports the lower end of the outer cylinder 12. A sealing member 19 such as an O-ring is provided between the flange 18 and the lower end of the outer cylinder 12. The interior of the outer cylinder 12 is thereby maintained airtight.

A support 20 having an annular shape is provided on the upper inner wall of the manifold 17. The support 20 supports the lower end of the inner cylinder 11. A lid body 21 is airtightly attached to the opening of the lower end of the manifold 17 through a sealing member 22 such as an O-ring. Thus, the opening at the lower end of the processing chamber 10, namely the opening of the manifold 17, is airtightly closed. The lid body 21 is formed of, for example, stainless steel.

A rotary shaft 24 is provided penetrating the center of the lid body 21 through a magnetic fluid seal 23. The lower part of the rotary shaft 24 is rotatably supported by an arm 25A of an elevating mechanism 25 composed of a boat elevator.

A rotary plate 26 is provided at the upper end of the rotary shaft 24. The boat 16 for holding a plurality of substrates W is mounted on the rotary plate 26, with a quartz heat insulation table 27 provided between the boat 16 and the rotary plate 26. The boat 16 rotates by rotation of the rotary shaft 24. The boat 16 moves up and down together with the lid body 21 by raising and lowering the elevating mechanism 25, thereby allowing the boat 16 to be inserted into and removed from the processing chamber 10. The boat 16 can be accommodated in the processing chamber 10. The boat 16 holds the plurality of substrates W in a shelf-like manner. The boat 16 holds the plurality of substrates W substantially horizontally at intervals in the vertical direction.

The gas supply 30 is configured so as to introduce various process gases into the inner cylinder 11. The gas supply 30 includes a dichlorosilane gas supply 31, an ethylene gas supply 32, an ammonia gas supply 33, and a hydrogen fluoride gas supply 34.

The dichlorosilane gas supply 31 includes a gas supply pipe 31a inside the processing chamber 10, and a supply channel 31b outside the processing chamber 10. In the supply channel 31b, a dichlorosilane gas source 31c, a mass flow controller 31d, and a valve 31e are provided in this order from the upstream side to the downstream side in a gas flow direction. This configuration allows the supply timing of dichlorosilane gas in the gas source 31c to be controlled by the valve 31e, and the flow rate to be adjusted to a predetermined level by the mass flow controller 31d. Dichlorosilane gas flows into the gas supply pipe 31a from the supply channel 31b, and is discharged from the gas supply pipe 31a into the processing chamber 10. Dichlorosilane gas is an example of a silicon-containing gas.

The ethylene gas supply 32 includes a gas supply pipe 32a inside the processing chamber 10, and a supply channel 32b outside the processing chamber 10. In the supply channel 32b, a gas source 32c of ethylene gas, a mass flow controller 32d, and a valve 32e are provided in this order from the upstream side to the downstream side in a gas flow direction. This configuration allows the supply timing of ethylene gas in the gas source 32c to be controlled by the valve 32e, and the flow rate to be adjusted to a predetermined level by the mass flow controller 32d. Ethylene gas flows into the gas supply pipe 32a from the supply channel 32b, and is discharged from the gas supply pipe 32a into the processing chamber 10. Ethylene gas is an example of a carbon-containing gas.

The ammonia gas supply 33 is provided with a gas supply pipe 33a inside the processing chamber 10 and a supply channel 33b outside the processing chamber 10. In the supply channel 33b, a gas source 33c of ammonia gas, a mass flow controller 33d, and a valve 33e are provided in this order from the upstream side to the downstream side in a gas flow direction. This configuration allows the supply timing of ammonia gas in the gas source 33c to be controlled by the valve 33e, and the flow rate to be adjusted to a predetermined level by the mass flow controller 33d. Ammonia gas flows into the gas supply pipe 33a from the supply channel 33b, and is discharged from the gas supply pipe 33a into the processing chamber 10. Ammonia gas is an example of a nitride gas and a basic gas.

The hydrogen fluoride gas supply 34 includes a gas supply pipe 34a inside the processing chamber 10, and a supply channel 34b outside the processing chamber 10. The supply channel 34b is provided with a gas source 34c of hydrogen fluoride gas, a mass flow controller 34d, and a valve 34e in this order from the upstream side to the downstream side in a gas flow direction. This configuration allows the supply timing of hydrogen fluoride gas from the gas source 34c to be controlled by the valve 34e, and the flow rate to be adjusted to a predetermined level by the mass flow controller 34d. Hydrogen fluoride gas flows into the gas supply pipe 34a from the supply channel 34b, and is discharged from the gas supply pipe 34a into the processing chamber 10. Hydrogen fluoride gas is an example of a fluorine-containing gas.

The gas supply pipes 31a, 32a, 33a, and 34a are fixed to the manifold 17. The gas supply pipes 31a, 32a, 33a, and 34a are formed of, for example, quartz. The gas supply pipes 31a, 32a, 33a, and 34a extend linearly in the vertical direction in the vicinity of the inner cylinder 11, bend in an L-shape in the manifold 17 and extend in the horizontal direction, thereby penetrating the manifold 17. The gas supply pipes 31a, 32a, 33a, and 34a are provided side by side along the circumferential direction of the inner cylinder 11 and are formed at the same height.

A plurality of discharge ports 31f are provided in a portion of the gas supply pipe 31a located in the inner cylinder 11. The plurality of discharge ports 31f are provided at predetermined intervals along the vertical direction. The plurality of discharge ports 31f discharge gas horizontally toward the substrate W from the outside in the radial direction of the substrate W. The gas supply pipes 32a, 33a, and 34a are also provided with a plurality of discharge ports 32f, 33f, and 34f, respectively, similar to the gas supply pipe 31a.

The gas supply 30 may mix a plurality of kinds of gases and discharge the mixed gas from one gas supply pipe. The gas supply pipes 31a, 32a, 33a, and 34a may have shapes and arrangements different from each other. The gas supply 30 may further include a gas supply pipe for supplying another gas, for example, an inert gas.

The exhaust assembly 40 includes a gas outlet 41, an exhaust channel 42, a pressure regulating valve 43, and a vacuum pump 44. The gas outlet 41 is an upper side wall of the manifold 17 and is formed above the support 20. The exhaust channel 42 is connected to the gas outlet 41. The pressure regulating valve 43 is provided in the exhaust channel 42. The vacuum pump 44 is provided downstream of the pressure regulating valve 43 in the exhaust channel 42. The exhaust assembly 40 exhausts the gas in the processing chamber 10 by the vacuum pump 44 while the pressure in the processing chamber 10 is regulated by the pressure regulating valve 43. The gas in the inner cylinder 11 passes through the opening 15, a space P1 between the inner cylinder 11 and the outer cylinder 12, and the gas outlet 41 in this order, and is exhausted from the processing chamber 10.

The heater 50 is provided around the outer cylinder 12. The heater 50 is provided, for example, on a base plate 28. The heater 50 has a cylindrical shape so as to enclose the outer cylinder 12. The heater 50 includes, for example, a heating element and heats each substrate W in the processing chamber 10.

The controller 90 is an electronic circuit such as a CPU (central processing unit), an FPGA (field programmable gate array), and an ASIC (application specific integrated circuit). The controller 90 executes various control operations described herein by executing instruction codes stored in a memory or by designing a circuit for a special application.

### Film-Forming Method

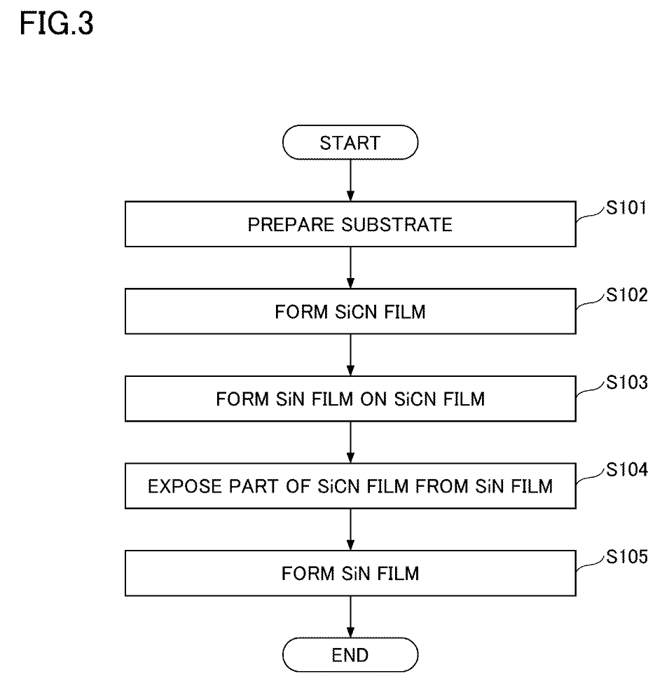

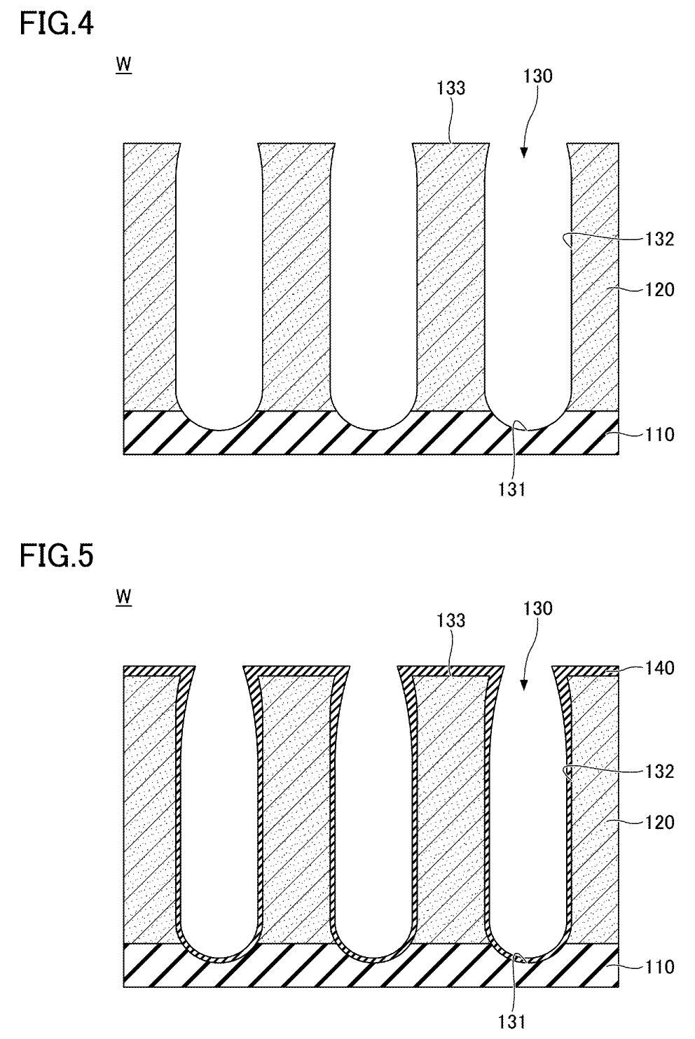

FIG. 3 is a flowchart illustrating a film-forming method according to an embodiment. FIGS. 4 through 8 are cross-sectional views illustrating a film-forming method according to an embodiment. The film-forming method according to the embodiment includes steps S101 through S105 illustrated in FIG. 3.

In step S101, the controller 90 controls the film-forming apparatus 1 so as to load the boat 16 holding the plurality of substrates W into the processing chamber 10 by raising the arm 25A, to airtightly close the opening at the lower end of the processing chamber 10 by the lid body 21, and to depressurize the inside of the processing chamber 10. As illustrated in FIG. 4, each substrate W includes a base film 110 and a core material 120. The base film 110 is, for example, a silicon nitride film. The core material 120 is formed on the base film 110. The core material 120 constitutes a protrusion relative to the base film 110. The core material 120 is, for example, a silicon film. Alternatively, the core material 120 may be a silicon oxide film. The base film 110 and the core material 120 form recesses 130. Each recess 130 includes a bottom surface 131 formed by the base film 110 and side surfaces 132 formed by the core material 120. The surfaces of the core material surrounding the recesses 130 are denoted as "top surfaces 133".

In step S102, as illustrated in FIG. 5, the controller 90 controls the film-forming apparatus 1 so as to form a SiCN film 140 on the surfaces of the recesses 130 and on the top surfaces 133 surrounding the recesses 130. The SiCN film 140 is an example of a protective film. For example, the controller 90 controls the gas supply 30 and the heater 50 so as to non-simultaneously supply dichlorosilane gas, ethylene gas, and ammonia gas into the processing chamber 10 while the temperature of each substrate W in the processing chamber 10 is maintained at a first temperature. Thus, the SiCN film 140 can be formed on the surfaces of the recesses 130 so as to coat the entire bottom surfaces 131 and side surfaces 132 of the recesses 130, and the top surfaces 133 surrounding the recesses 130. The first temperature may be equal to or greater than 550 °C and equal to or less than 650 °C, for example, 630 °C. The controller 90 may control the gas supply 30 so as to simultaneously supply dichlorosilane gas, ethylene gas, and ammonia gas into the processing chamber 10 while the temperature of each substrate W in the processing chamber 10 is maintained at the first temperature.

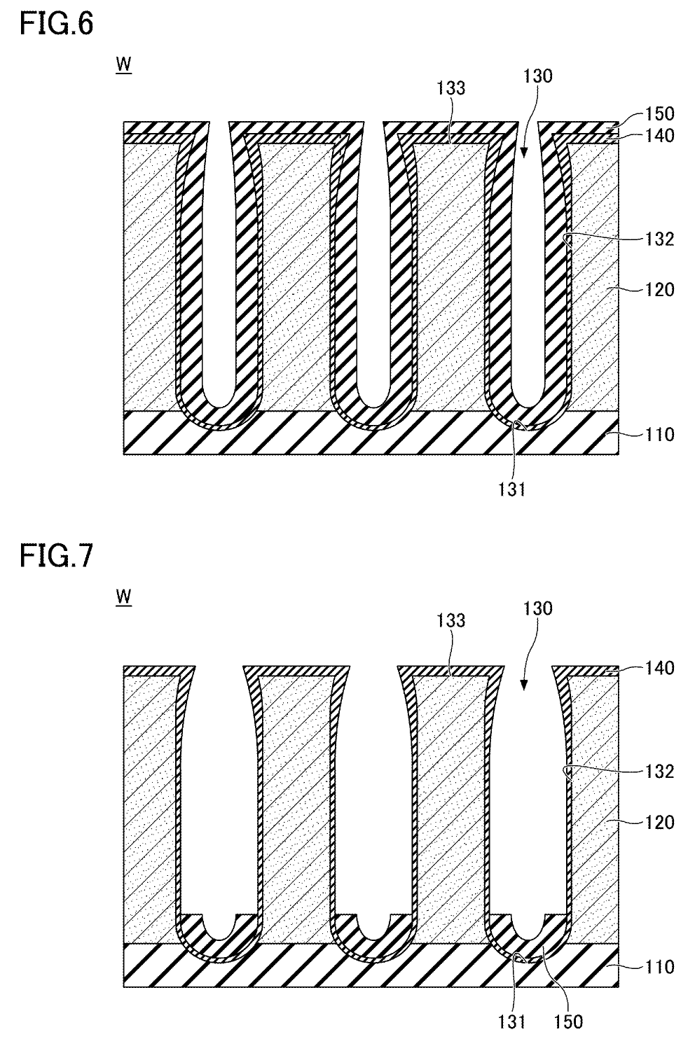

In step S103, as illustrated in FIG. 6, the controller 90 controls the film-forming apparatus 1 so as to form the SiN film 150 on the SiCN film 140. The SiN film 150 is an example of a first nitride film. For example, the controller 90 controls the gas supply 30 and the heater 50 so as to non-simultaneously supply dichlorosilane gas and ammonia gas into the processing chamber 10 while the temperature of each substrate W in the processing chamber 10 is maintained at a second temperature. Thus, the SiN film 150 can be formed so as to coat the entire surface of the SiCN film 140. The second temperature may be equal to or greater than 400 °C and equal to or less than 800 °C, for example, 630 °C. The controller 90 may control the gas supply 30 so as to simultaneously supply dichlorosilane gas and ammonia gas into the processing chamber 10 while the temperature of each substrate W in the processing chamber 10 is maintained at the second temperature.

In step S104, as illustrated in FIG. 7, the controller 90 controls the film-forming apparatus 1 so as to expose the SiCN film 140 on the side surfaces 132 of the recesses 130 and the top surfaces 133 surrounding the recesses 130 by etching the SiN film 150. For example, the controller 90 controls the gas supply 30 and the heater 50 so as to simultaneously supply hydrogen fluoride gas and ammonia gas into the processing chamber 10 while the temperature of each of the substrate W in the processing chamber 10 is maintained at a third temperature. As a result, ammonium silicofluoride [(NH₄)₂SiF₆] is formed through a reaction between the SiN film 150 and the hydrogen fluoride gas and the ammonia gas. The hydrogen fluoride gas and the ammonia gas are more likely to react with the SiN film 150 on the side surfaces 132 and the top surfaces 133 than on the bottom surfaces 131 of the recesses 130. Therefore, ammonium silicofluoride is selectively formed on the SiN film 150 on the side surfaces 132 and the top surfaces 133 as compared with the bottom surfaces 131 of the recesses 130. The third temperature may be equal to or greater than 50 °C and equal to or less than 100 °C, for example, 75 °C. Next, the controller 90 controls the gas supply 30 and the heater 50 so as to change and maintain the temperature of each substrate W in the processing chamber 10 to a fourth temperature while supplying an inert gas such as nitrogen gas into the processing chamber 10. The fourth temperature is equal to or greater than the temperature at which the ammonium silicofluoride is sublimated. Thus, the ammonium silicofluoride is sublimated, and the SiN film 150 is removed from the SiCN film 140. At this time, ammonium silicofluoride is selectively formed on the side surfaces 132 and the top surfaces 133 as compared with the bottom surfaces 131 of the recesses 130. Therefore, the SiCN film 140 can be exposed on the side surfaces 132 of the recesses 130 and the top surfaces 133 surrounding the recesses 130 while the SiN film 150 formed on the bottom surfaces 131 of the recesses 130 remains. The fourth temperature may be equal to or greater than 200 °C, for example, 300 °C. Here, the SiCN film 140 has a property of not readily reacting with hydrogen fluoride gas and ammonia gas. Therefore, even if the SiCN film 140 is exposed to hydrogen fluoride gas and ammonia gas by over-etching after the SiCN film 140 is exposed from the SiN film 150, the SiCN film 140 is not appreciably etched and the surfaces of the recesses 130 and the top surfaces 133 surrounding the recesses 130 are protected. As a result, etching damage to the surfaces of the recesses 130 and the top surfaces 133 surrounding the recesses 130 can be reduced.

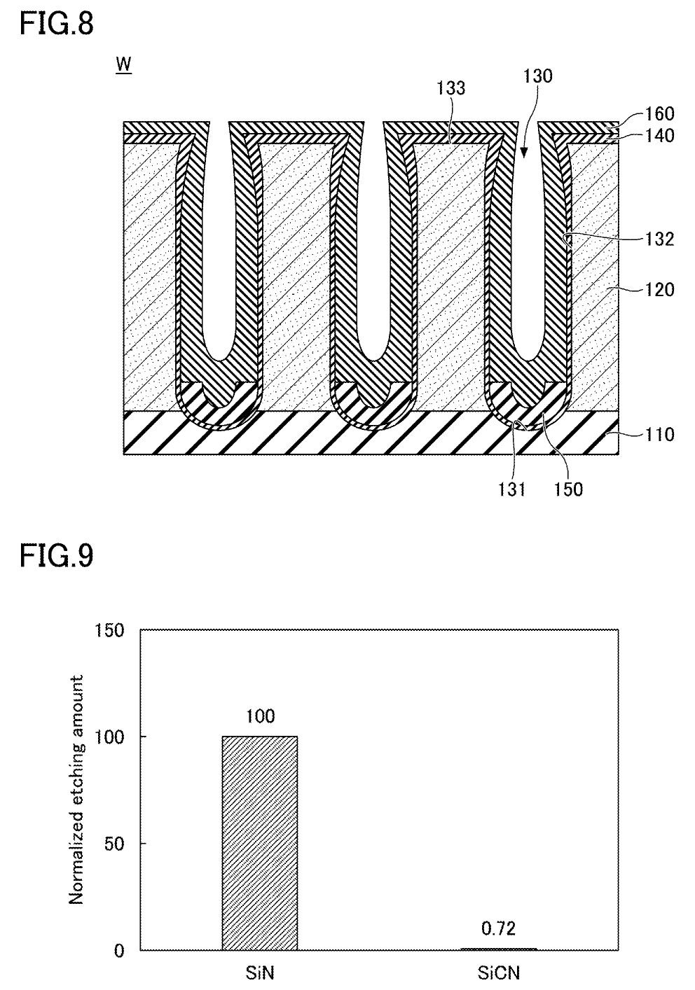

In step S105, as illustrated in FIG. 8, the controller 90 controls the film-forming apparatus 1 so that the SiN film 160 is formed on the SiCN film 140 and the SiN film 150. The SiN film 160 is an example of a second nitride film. For example, the controller 90 controls the gas supply 30 so as to non-simultaneously supply dichlorosilane gas and ammonia gas into the processing chamber 10. Thus, the SiN film 160 can be formed on the SiCN film 140 and the SiN film 150. However, the controller 90 may control the gas supply 30 so as to simultaneously supply dichlorosilane gas and ammonia gas.

After step S105, the controller 90 controls the gas supply 30, the exhaust assembly 40, and the heater 50 so as to increase the pressure in the processing chamber 10 to atmospheric pressure and lower the temperature in the processing chamber 10 to an unloading temperature. Next, the controller 90 controls the film-forming apparatus 1 so as to lower the arm 25A and unload the boat 16 from the processing chamber 10. Thus, the processing for each substrate W held in the boat 16 is completed.

As described above, according to the film-forming method according to the embodiment, when the recesses 130 are filled with a SiN film, SiN film 150 formation, SiN film 150 etching, and subsequent SiN film 160 formation are performed in this order. During the etching of the SiN film 150, the SiCN film 140 is exposed on the side surfaces 132 of the recesses 130 and the top surfaces 133 surrounding the recesses 130 while the SiN film 150 formed on the bottom surfaces 131 of the recesses 130 remains. When the SiN film 160 is formed, the SiN film 160 grows from the bottom surfaces 131 of the recesses 130. As a result, the recesses 130 can be filled with the SiN film 160 with almost no voids or seams. When the recesses 130 are filled with the SiN film, the surfaces of the recesses 130 are coated with the SiCN film 140 before SiN film 150 formation, SiN film 150 etching, and SiN film 160 formation are performed in this order. In this case, even if over-etching is performed when the SiN film 150 is etched, the SiCN film 140 is not appreciably etched and the surfaces of the recesses 130 and the top surfaces 133 surrounding the recesses 130 are protected. As a result, etching damage to the surfaces of the recesses 130 and the top surfaces 133 surrounding the recesses 130 can be reduced.

### First Experiment

In the first experiment, the etching resistance of the SiN film and the SiCN film to hydrogen fluoride gas and ammonia gas was evaluated.

First, a substrate having a SiN film on its surface and a substrate having a SiCN film on its surface were prepared. Next, hydrogen fluoride gas and ammonia gas were supplied to each of the prepared substrates for 800 seconds while the temperature of each of the substrates was maintained at 75 °C, and then an etching process was performed while the temperature of the substrate was increased to 300 °C and maintained. The thicknesses of the SiN film and the SiCN film were measured before and after the etching process. Next, the difference between the SiN film thicknesses measured before and after the etching process was defined as the etching amount of the SiN film. Similarly, the difference between the SiCN film thicknesses measured before and after the etching process was defined as the etching amount of the SiCN film.

FIG. 9 illustrates the etching amounts of the SiN film and the SiCN film. In FIG. 9, the etching amounts of the SiN film and the SiCN film are expressed as relative values when the etching amount of the SiN film is 100.

As illustrated in FIG. 9, when the etching amount of the SiN film is 100, the etching amount of the SiCN film is 0.72. This result showed that the SiCN film had higher etching resistance than the SiN film to hydrogen fluoride gas and ammonia gas.

### Second Experiment

In the second experiment, it was confirmed whether the SiCN film functioned as a protective film to reduce etching damage to the surfaces of the recesses and the surfaces surrounding the recesses when the SiN film formed on the surfaces of the recesses and the surfaces surrounding the recesses was etched with hydrogen fluoride gas and ammonia gas.

First, a substrate A and a substrate B, each having recesses on their surfaces, were prepared. In these substrates, the surfaces of the recesses were not covered with a SiCN film, and the entire surfaces of the recesses were covered with a SiN film. A substrate C having recesses on its surface was also prepared. In the substrate C, the entire surfaces of the recesses were covered with a SiCN film, and the entire surface of the SiCN film was covered with a SiN film. The film thickness of the SiCN film was 4 nm. A base film and a core material form a plurality of recesses.

Next, hydrogen fluoride gas and ammonia gas were supplied to the substrate A while the temperature of the substrate A was maintained at 75 °C, and then an etching process was performed while the temperature of the substrate A was increased to and maintained at 300 °C. The etching time of the substrate A was adjusted so that the surfaces of the recesses and the surfaces surrounding the recesses were not exposed from the SiN film.

Hydrogen fluoride gas and ammonia gas were supplied to the substrate B while the temperature of the substrate B was maintained at 75 °C, and then an etching process was performed while the temperature of the substrate B was increased to and maintained at 300 °C. The etching time of the substrate B was adjusted so that the upper portions of the side surfaces of the recesses and the top surfaces surrounding the recesses were exposed from the SiN film.

Hydrogen fluoride gas and ammonia gas were supplied to the substrate C while the temperature of the substrate C was maintained at 75 °C, and then an etching process was performed while the temperature of the substrate C was increased to and maintained at 300 °C. The etching time of the substrate C was adjusted so that the SiCN film, which is covered with the SiN film, was exposed on the upper portions of the side surfaces of the recesses and the top surfaces surrounding the recesses.

Next, cross-sectional images of the substrates A, B, and C were obtained by transmission electron microscopy (TEM). The width of the core material at the upper portions of the side surfaces of the recesses was measured in each of the cross-sectional images of the substrates A, B, and C.

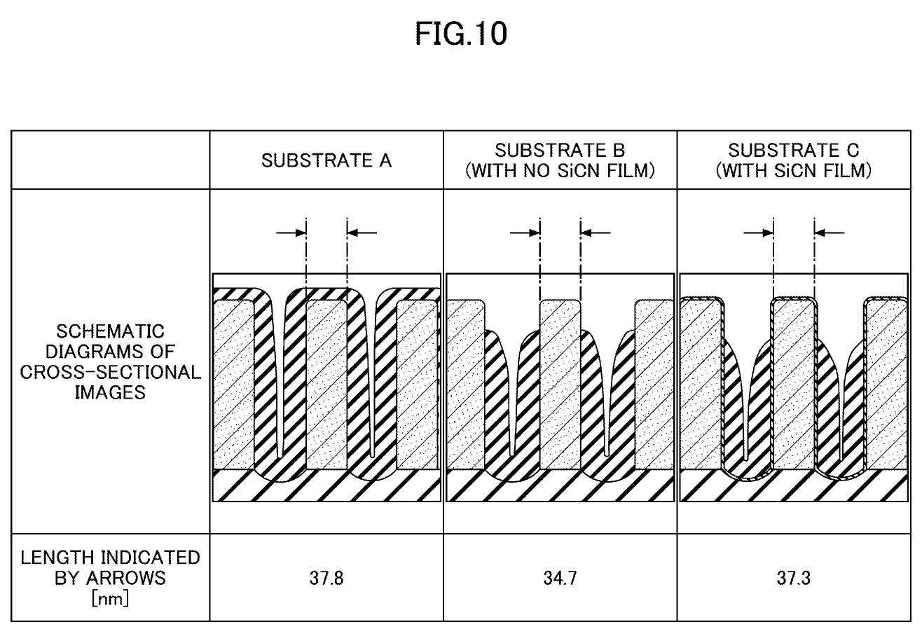

FIG. 10 is of schematic views of examples of the cross-sectional images. FIG. 10 illustrates schematic views of the cross-sectional images of the substrates A, B, and C, and the width of the core material (length indicated by an arrow in FIG. 10).

As illustrated in FIG. 10, the width of the core material of the substrate A was 37.8 nm, the width of the core material of the substrate B was 34.7 nm, and the width of the core material of the substrate C was 37.3 nm. Since the width of the core material of the substrate C was almost the same as the width of the core material of the substrate A, it is considered that the surfaces of the recesses and the surfaces surrounding the recesses of the substrate C were not damaged by over-etching of the SiN film. Since the width of the core material of the substrate B was shorter than the width of the core material of the substrate A, it is considered that the surfaces of the recesses and the surfaces surrounding the recesses of the substrate B were damaged by over-etching of the SiN film. These results showed that the SiCN film functioned as a protective film to reduce the etching damage to the surfaces of the recesses and the surfaces surrounding the recesses.

### Third Experiment

In the third experiment, the surfaces of the recesses and the surfaces surrounding the recesses were first covered with a SiCN film. The effect of this SiCN layer on the gap-filling characteristics of SiN in the recesses was then evaluated using a deposition-etch-deposition process consisting of (1) SiN deposition, (2) SiN etching, and (3) SiN deposition.

First, a substrate D having recesses on its surface was prepared. In the substrate D, the surfaces of the recesses and the surfaces surrounding the recesses were not covered with a SiCN film, and the entire surfaces of the recesses and the surfaces surrounding the recesses were covered with a SiN film. A substrate E having recesses on its surface was also prepared. In the substrate E, the entire surfaces of the recesses and the surfaces surrounding the recesses were covered with a SiCN film and the entire surface of the SiCN film was covered with a SiN film. The film thickness of the SiCN film was 4 nm. A base film and a core material form the recesses.

Next, hydrogen fluoride gas and ammonia gas were supplied to the substrate D while the temperature of the substrate D was maintained at 75 °C, and then an etching process was performed while the temperature of the substrate D was increased to and maintained at 300 °C. The etching time of the substrate D was adjusted so that the surfaces of the recesses were exposed on the upper surfaces of the side surfaces of the recesses and the upper surfaces surrounding the recesses.

Hydrogen fluoride gas and ammonia gas were supplied to the substrate E while the temperature of the substrate E was maintained at 75 °C, and then an etching process was performed while the temperature of the substrate E was increased to and maintained at 300 °C. For the substrate E, the etching time was adjusted so that the SiCN film on the upper portions of the side surfaces of the recesses and the upper surfaces surrounding the recesses was exposed from the SiN film.

Next, a SiN film was formed on the substrates D and E until the recesses were completely filled with the SiN film.

Next, cross-sectional images of the substrates D and E were obtained by transmission electron microscopy. Based on the cross-sectional images of the substrates D and E, the size of the seam in the recesses was measured. As a result of the measurement, the size of the seam in the substrate E was smaller than that in the substrate D. The result showed that the gap-filling characteristics of SiN in the recesses can be improved by covering the surfaces of the recesses with a SiCN film before the SiN film deposition, the SiN film etching, and the SiN film deposition, which were performed in this order.

The embodiments disclosed herein should be considered illustrative and not restrictive in all respects. The foregoing embodiments may be omitted, substituted or modified in various ways without departing from the scope and intent of the appended claims.

In the foregoing embodiments, the case where the film-forming apparatus is a batch-type apparatus for processing a plurality of substrates in a batch has been described, but the present disclosure is not limited to this example. For example, the film-forming apparatus may be a single-wafer type apparatus for processing substrates one by one.

In the foregoing embodiments, the case where the SiCN film 140 is exposed from the SiN film 150 on the side surfaces 132 of the recesses 130 and the top surfaces 133 surrounding the recesses 130 has been described in step S104, but the present disclosure is not limited to this example. In step S104, a part of the SiCN film 140 may be exposed from the SiN film 150. For example, in step S104, the SiCN film 140 may be exposed on the upper portions of the side surfaces 132 of the recesses 130 and the top surfaces 133 surrounding the recesses 130 while the SiN film 150 formed on the bottom surfaces 131 and the lower portions of the side surfaces 132 of the recesses 130 remains. For example, in step S104, the SiCN film 140 may be exposed on the top surfaces 133 surrounding the recesses 130 while the SiN film 150 formed on the bottom surfaces 131 and the side surfaces 132 of the recesses 130 remains.

In the foregoing embodiment, the case where the protective film is a SiCN film has been described, but the present disclosure is not limited to this example. The protective film may be any film having etching resistance higher than that of the SiN film against etching gas. The protective film may be a BN film or a SiBN film. The protective film may be a stacked film of at least two kinds among a SiCN film, a BN film, and a SiBN film.

In the foregoing embodiments, a case where the first nitride film and the second nitride film are SiN films has been described, but the present disclosure is not limited to this example. The first nitride film and the second nitride film may be an oxynitride film such as a SiON film. The first nitride film and the second nitride film may be different films.

In the foregoing embodiments, the case where the silicon-containing gas is dichlorosilane gas is described, but the present disclosure is not limited to this example. The silicon-containing gas may be a silicon gas containing a halogen such as fluorine (F), chlorine (Cl), or bromine (Br). The fluorine-containing silicon gas may be, for example, SiF₄ gas, SiHF₃ gas, SiH₂F₂ gas, SiH₃F gas, or a combination of these gases. The chlorine-containing silicon gas may be, for example, SiCl₄ gas, SiHCl₃ gas, SiH₂Cl₂ gas, SiH₃Cl gas, Si₂Cl₆ gas, or a combination of these gases. The bromine-containing silicon gas may be, for example, SiBr₄ gas, SiHBr₃ gas, SiH₂Br₂ gas, SiH₃Br gas, or a combination of these gases.

In the foregoing embodiments, the case where the carbon-containing gas is ethylene gas has been described, but the present disclosure is not limited to this example. The carbon-containing gas may be a CₓH_{y} gas (x and y are integers of 1 or greater). The CₓH_{y} gas may be, for example, ethylene (C₂H₄) gas, propane (C₃H₈) gas, or a combination of these gases.

In the foregoing embodiments, the nitriding gas is ammonia gas, but the present disclosure is not limited to this example. As the nitriding gas, for example, ammonia gas, diazene gas, hydrazine gas, monomethylhydrazine gas, trimethylamine gas, or a combination of these gases can be used.

In the foregoing embodiments, the basic gas is ammonia gas, but the present disclosure is not limited to this example. As the basic gas, for example, ammonia gas, dimethylamine gas, trimethylamine gas, hydrazine gas, or a combination of these gases can be used.

In the foregoing embodiments, the fluorine-containing gas is hydrogen fluoride gas, but the present disclosure is not limited to this example. As the fluorine-containing gas, for example, fluorine gas, chlorine trifluoride gas, nitrogen trifluoride gas, or a combination of these gases can be used.

What is claimed is:

1. A film-forming method comprising:
forming a protective film on a surface of a recess formed in a substrate and on a surface surrounding the recess;
forming a first nitride film on the protective film;
exposing a part of the protective film from the first nitride film while the first nitride film that is formed on a bottom surface of the recess remains, by supplying an etching gas to the substrate; and
forming a second nitride film on the protective film and the first nitride film after the exposing of the part of the protective film, wherein
the protective film has a higher etching resistance to the etching gas than the first nitride film.

2. The film-forming method according to claim 1, wherein
in the forming of the protective film, an entire surface of the recess is covered with the protective film.

3. The film-forming method according to claim 1, wherein
the etching gas includes a fluorine-containing gas and a basic gas.

4. The film-forming method according to claim 1, wherein
the protective film is a SiCN film, a SiBN film, a BN film, or a combination of the SiCN film, the SiBN film, and the BN film.

5. The film-forming method according to claim 1, wherein
the first nitride film and the second nitride film are SiN films.

6. A film-forming apparatus comprising:
a controller configured to control the film-forming apparatus, wherein
the controller is configured to cause the film-forming apparatus to perform:
forming a protective film on a surface of a recess formed in a substrate and on a surface surrounding the recess;
forming a first nitride film on the protective film;
exposing a part of the protective film from the first nitride film while the first nitride film that is formed on a bottom surface of the recess remains, by supplying an etching gas to the substrate; and
forming a second nitride film on the protective film and the first nitride film after the exposing of the part of the protective film, and
the protective film has a higher etching resistance to the etching gas than the first nitride film.
